(19) United States
(12) Patent Application Publication
(10) Pub. No.: US 2026/0314273 A1
(43) Pub. Date: Oct. 8, 2026

(54) MULTIFUNCTIONAL LOW-POWER OPTOELECTRONIC MEMRISTORS DEVICE AND METHOD OF MANUFACTURING THEREOF

(71) Applicant: KOREA UNIVERSITY RESEARCH AND BUSINESS FOUNDATION, Seoul (KR)

(72) Inventors: Jae Won SHIM, Seoul (KR); Min Jong LEE, Seoul (KR)

(21) Appl. No.: 19/549,394

(22) Filed: Feb. 25, 2026

(30) Foreign Application Priority Data
Apr. 2, 2025 (KR) 10-2025-0043075

(51) Int. Cl. H10N 70/00

(52) U.S. Cl. CPC H10N 70/881; H10N 70/026

(57) ABSTRACT

A multifunctional low-power optoelectronic memristor device is disclosed. The multifunctional low-power optoelectronic memristor device includes: a bottom electrode layer; an intermediate layer formed on the bottom electrode layer and including titanium dioxide (TiO2); a resistive switching layer formed on the intermediate layer and configured to switch a resistance state; an upper protective layer formed on the resistive switching layer; and a top electrode layer formed on the upper protective layer, wherein the resistive switching layer is a halide perovskite material layer.

### CROSS-REFERENCE TO RELATED APPLICATION

This application claims under 35 U.S.C. § 119 (a) the benefit of Korean Patent Application No. 10-2025-0043075, filed on Apr. 2, 2025, the entire contents of which is incorporated herein by reference.

### BACKGROUND

### (a) Technical Field

The present disclosure relates to a multifunctional low-power optoelectronic memristor device and method of manufacturing thereof.

### (b) Background Art

Conventional memristor technology is used to integrate non-volatile memory and logic circuits, and mainly stores and processes data by switching electrical resistance states. Such technology enables low power consumption and high-speed switching and has attracted attention in neural-network-based computing applications.

However, conventional halide-perovskite-based memristors suffer from increased instability of conductive filaments due to interface and bulk defects formed during a manufacturing process, which makes it difficult to control resistive switching.

In addition, conventional memristors require high operating voltage and high forming voltage, which leads to excessive power consumption and makes them unsuitable for low-power systems such as IoT (Internet of Things). Further, due to irregularity in filament formation and rupture, a large cell-to-cell variation in switching voltages occurs, which degrades reliability and reproducibility.

Further, conventional memristors have low photo-responsivity, which limits implementation of multi-modal functions using not only electrical input but also optical input. In addition, perovskite materials are sensitive to ambient environments (e.g., heat and humidity), making it difficult to secure long-term stability.

These issues act as major factors hindering commercialization of memristor technology and reveal limitations in meeting performance requirements demanded in IoT and energy-efficient computing systems. Examples of resistive switching layer materials studied for implementing low-power memristors and their limitations are shown in Table 1 below.

TABLE 1

| resistive | | |
|---|---|---|
| switching | | |
| layer materials | Effect | Limitation |
| Graphene/SiO₂ | Electroluminescence spectrum | Emission intensity |
| | in a range of 400~1100 nm, | decreases when voltage |
| | peak shifts to 550 nm in HRS | increases (above 6 V), |
| | and 770 nm in LRS. | and a high operating |
| | ON/OFF ratio of about 10⁵, | voltage is required |
| | with stable optical output | |
| | confirmed at 7.5 V | |
| TaOₓ/Al₂O₃ | An Al₂O₃ insertion layer | Although an insertion |
| | with a thickness of 2 nm | layer is added, excessive |
| | increases the ON/OFF ratio by | control of oxygen-ion |
| | about 148 times and lowers | diffusion increases |
| | switching voltages to | switching non- |
| | 0.61 V/−0.49 V. | uniformity. |
| Silk | Achieves an ON/OFF ratio of | Low physical stability, |
| Fibroin | 10⁴ by leveraging | leading to limitations |
| | biocompatibility | in long-term durability. |
| | and biodegradability and | |
| | minimizes environmental | |
| | impacts. | |
| CsPbI₃ | Operating voltage of 0.18 V, | Electrical characteristics |
| | ON/OFF ratio of 10⁶ | degrade after 4 days in |
| | or higher, implementation of | air due to phase |
| | four multi-level switching | transition (RESET |
| | memory states, and | voltage increases |
| | preservation of electrical | from −0.1 V |
| | characteristics | to −0.16 V). |
| | even on flexible substrates. | |

### SUMMARY OF THE DISCLOSURE

The present disclosure is directed to providing a multifunctional low-power optoelectronic memristor device.

The present disclosure is also directed to providing a multifunctional low-power optoelectronic memristor device in which a TiO₂ nanofilm reduces interface defects and improves switching performance and uniformity.

The present disclosure is also directed to providing a multifunctional low-power optoelectronic memristor device that enables low-power operation, integrates optical/electrical inputs, and provides high stability and durability.

The present disclosure is also directed to providing a multifunctional low-power optoelectronic memristor device that is capable of multifunctional logic operations and image recognition and that integrates memory, sensing, and logic operations, thereby being applicable to IoT and energy-efficient systems.

The present disclosure is also directed to providing a multifunctional low-power optoelectronic memristor device that can significantly enhance efficiency and feasibility of IoT and next-generation computing through low-power, high-performance, multifunctional memristors.

According to one aspect of the present disclosure, a multifunctional low-power optoelectronic memristor device is provided.

According to one embodiment of the present disclosure, the multifunctional low-power optoelectronic memristor device may include: a bottom electrode layer; an intermediate layer formed on the bottom electrode layer and including titanium dioxide (TiO₂); a resistive switching layer formed on the intermediate layer and configured to switch a resistance state; an upper protective layer formed on the resistive switching layer; and a top electrode layer formed on the upper protective layer, wherein the resistive switching layer is a halide perovskite material layer.

The intermediate layer may be formed to a thickness of 1 nm to 5 nm by atomic layer deposition (ALD), and has a thickness of 5 nm to control a formation position and a size of a conductive filament in the halide perovskite material layer.

The halide perovskite material layer may include CsPbI₃.

When a voltage is applied to the bottom electrode layer and the top electrode layer, the titanium dioxide (TiO₂) binds to electron-donating defects in the halide perovskite material layer to remove recombination centers, thereby controlling a formation position and a size of a filament.

As a first voltage is applied, silver ions (Ag⁺) may be released from a top electrode (Ag) and migrate to a bottom electrode (FTO) through the resistive switching layer (CsPbI₃), and titanium dioxide (TiO₂) may bind to electron-donating defects in the resistive switching layer (CsPbI₃) to remove recombination centers, and the silver ions (Ag⁺) may form a metallic filament such that the resistive switching layer is set to a first resistance state. As a second voltage is applied, the metallic filament may rupture such that the resistive switching layer is set to a second resistance state.

A near-infrared laser having a wavelength of 730 nm may be irradiated, and photo-generated charges may be generated in the resistive switching layer (CsPbI₃) according to irradiation of the 730 nm near-infrared laser.

The first voltage may be 0.24 V, the first voltage and the second voltage may have opposite polarities.

### BRIEF DESCRIPTION OF DRAWINGS

FIG. 1 is a diagram schematically illustrating a structure of a multifunctional low-power optoelectronic memristor device according to an embodiment of the present disclosure.

FIG. 2 is a diagram illustrating I-V characteristics, switching voltages (V_{SET}, V_{RESET}), and endurance/retention analysis results of a multifunctional low-power optoelectronic memristor device.

FIG. 3 is a diagram illustrating an I-V curve showing an electroforming process according to an embodiment of the present disclosure.

FIG. 4 is a diagram illustrating results of investigating I-V characteristics according to insertion and thickness of various intermediate-layer materials.

FIG. 5 is a diagram illustrating results of investigating switching voltages (V_{SET}, V_{RESET}) and HRS/LRS ratios according to insertion and thickness of various intermediate-layer materials.

FIG. 6 is a diagram illustrating reliability and performance metrics of a conventional memristor device and a memristor device according to an embodiment of the present disclosure.

FIG. 7 is a diagram illustrating a comparison of key parameters a conventional a halide-perovskite-based photodetector and a memristor device according to an embodiment of the present disclosure.

FIG. 8 is a diagram illustrating distributions of HRS and LRS obtained by measuring resistances of 60 cells under voltage pulses of ±0.05 V in a multifunctional low-power optoelectronic memristor device according to an embodiment of the present disclosure.

FIG. 9 is a diagram illustrating a performance comparison of halide-perovskite-based memristors.

FIG. 10 is a diagram illustrating a comparison of electrical characteristics with respect to RS-layer materials of memristor devices.

FIG. 11 is a diagram illustrating a switching principle based on an electrochemical metallization (ECM) mechanism according to an embodiment of the present disclosure.

FIG. 12 is a diagram illustrating a nonlinear I-V curve of HRS for a DC voltage sweep applied from 0 V to +0.24 V in a multifunctional low-power optoelectronic memristor device according to an embodiment of the present disclosure.

FIG. 13 is a diagram illustrating I-V characteristics measured under a negative bias (0 V→−1 V→0 V→+1.5 V→0 V).

FIGS. 14 and 15 are diagrams illustrating I-V characteristics of a top electrode measured in a temperature range of 253-353 K according to an embodiment of the present disclosure.

FIG. 16 is a diagram illustrating an ON/OFF ratio measured with an inert top electrode to verify RS operation.

FIG. 17 is a diagram illustrating cross-sectional TEM and EDS mapping analysis results for conductive filament formation depending on presence/absence of titanium dioxide (TiO₂).

FIG. 18 is a diagram illustrating I-V characteristics showing that an upper protective layer (PMMA) does not affect RS operation but improves device stability by protecting against environmental factors.

FIG. 19 is a diagram illustrating I-V characteristics of a memristor device measured for 400 hours under ambient conditions (room temperature, relative humidity 30%).

FIG. 20 is a diagram illustrating long-term stability of HRS/LRS states of a memristor device measured for 400 hours under ambient conditions.

FIG. 21 is a diagram illustrating an XRD pattern showing characteristic peaks at 14.4° (110) and 29.0° (220).

FIG. 22 is a diagram illustrating a comparison of crystallinity and surface quality of a halide perovskite (CsPbI₃) layer depending on presence/absence of an intermediate layer including titanium dioxide (TiO₂) layer.

FIG. 23 is a diagram illustrating GIWAXS 2D images of a TiO₂/halide perovskite (CsPbI₃) film and a single halide perovskite (CsPbI₃) film according to an embodiment of the present disclosure.

FIG. 24 is a diagram illustrating GIWAXS intensity profiles (out-of-plane and in-plane) of a TiO₂/halide perovskite (CsPbI₃) film and a single halide perovskite (CsPbI₃) film according to an embodiment of the present disclosure.

FIG. 25 is a diagram illustrating top-view SEM images showing effects of DMAI content and a TiO₂ layer on morphology of a halide perovskite (CsPbI₃) thin film.

FIG. 26 is a diagram illustrating results comparing trap density and carrier density before and after inserting a titanium dioxide (TiO₂) layer.

FIG. 27 is a diagram illustrating a C-V curve of a memristor device and capacitance changes according to AC bias amplitude, according to an embodiment of the present disclosure.

FIG. 28 is a diagram illustrating a comparison of electrical responses to optical inputs in a multifunctional low-power optoelectronic memristor device according to an embodiment of the present disclosure.

FIG. 29 is a diagram illustrating logic operations and flip-flop implementation using both optical and electrical inputs based on a multifunctional low-power optoelectronic memristor device according to an embodiment of the present disclosure.

FIG. 30 is a diagram illustrating experiments demonstrating image recognition and non-volatile data storage using an array of multifunctional low-power optoelectronic memristor devices according to an embodiment of the present disclosure.

FIG. 31 is a process flowchart illustrating a method of manufacturing a multifunctional low-power optoelectronic memristor device according to an embodiment of the present disclosure.

### DETAILED DESCRIPTION

Singular forms used in this specification include plural forms unless the context clearly indicates otherwise. In the specification, the term “configured”, “include”, or the like should not be construed as necessarily including several components or several steps described herein, in which some of the components or steps may not be included or additional components or steps may be further included. Further, the terms “~ unit”, “module”, and the like mean a unit for processing at least one function or operation and may be implemented by hardware or software or by a combination of hardware and software.

Hereinafter, the embodiments of the present disclosure will be described in detail with reference to the accompanying drawings.

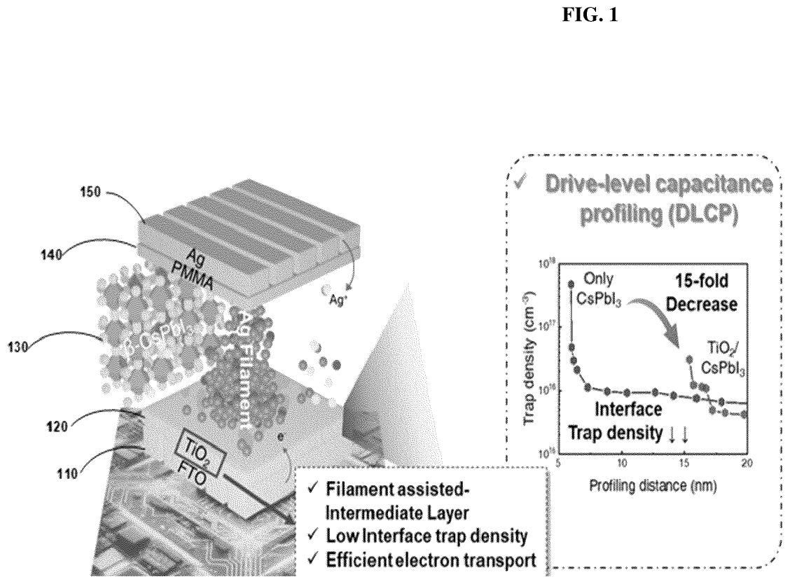

FIG. 1 is a diagram schematically illustrating a structure of a multifunctional low-power optoelectronic memristor device according to an embodiment of the present disclosure.

Referring to FIG. 1, the multifunctional low-power optoelectronic memristor device according to an embodiment of the present disclosure includes a bottom electrode layer 110, an intermediate layer 120, a resistive switching layer 130, an upper protective layer 140, and a top electrode layer 150.

The bottom electrode layer 110 serves to supply current. In one embodiment of the present disclosure, it is assumed that the bottom electrode layer 110 is formed of fluorine-doped tin oxide (FTO), and the description is provided mainly based on this assumption. The bottom electrode layer 110 may play an important role not only in electrical connection but also at an interface with the resistive switching layer.

The intermediate layer 120 is formed on the bottom electrode layer 110. The intermediate layer 120 serves to regulate electron transport between the resistive switching layer 130 and the bottom electrode layer 110 and may control diffusion of oxygen vacancies. According to one embodiment of the present disclosure, the intermediate layer 120 may be formed as a titanium dioxide (TiO₂) nanofilm.

The titanium dioxide (TiO₂) layer may be formed by atomic layer deposition (ALD) and may have a thickness of 1 to 5 nm. To control a formation position and a size of a conductive filament in the halide perovskite material layer, the thickness is preferably 5 nm.

Titanium dioxide (TiO₂) can chemically passivate defect states present at an interface between the resistive switching layer 130 and the bottom electrode layer 110, thereby reducing defect density by 15 times or more.

When a voltage is applied to the bottom electrode layer 110 and the top electrode layer 150, Ti⁴⁺ ions may bind to electron-donating defects (e.g., iodine vacancies) in a halide perovskite (CsPbI³), thereby removing recombination centers and minimizing defects in a charge-transport path. That is, when an electric field is applied and silver ions (Ag⁺) released from the top electrode migrate to the bottom electrode through the resistive switching layer, the titanium dioxide (TiO₂) layer may interact with electron-donating defects (e.g., iodine vacancies) in the halide perovskite (CsPbI₃) to form a potential barrier at the interface. Accordingly, charge recombination is suppressed, and a formation position and a size of a metallic filament formed by the ions (Ag⁺) can be controlled.

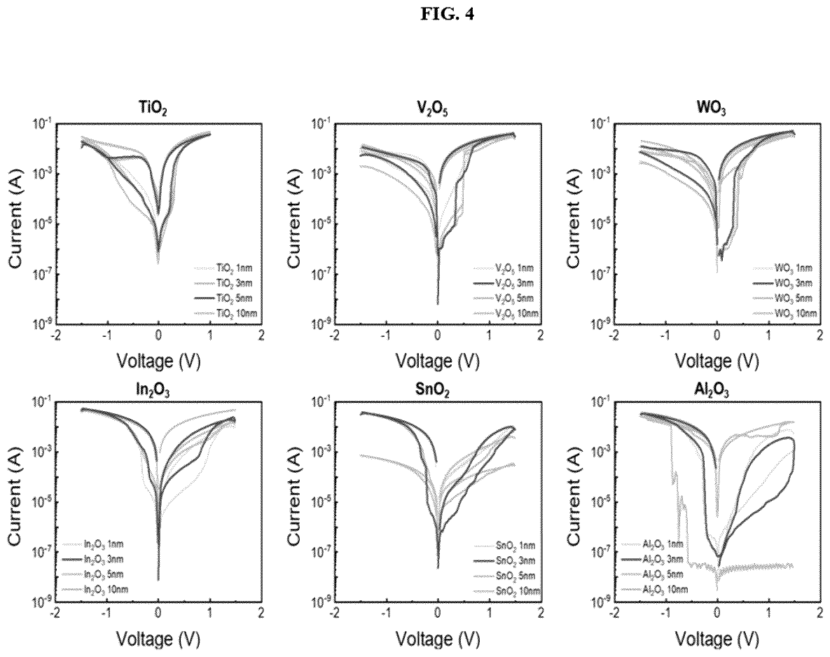

The resistive switching layer 130 is formed on the intermediate layer and serves to switch a resistance state. According to one embodiment of the present disclosure, the resistive switching layer 130 is a halide perovskite material layer and may include CsPbI₃. Electrical characteristics according to the resistive switching layer are as shown in FIG. 4.

The upper protective layer 140 may be formed on the resistive switching layer 130.

Here, the upper protective layer 140 may be made of polymethyl methacrylate (PMMA), and may block exposure to external air, moisture, oxygen, and the like to enhance stability of the memristor device and prevent oxidation or degradation.

The top electrode layer 150 may be formed on the upper protective layer 140. For example, the top electrode layer 150 may be formed of silver (Ag) and may serve to induce oxidation and metal-ion migration.

Summarizing the operating principle, as a first voltage is applied, silver ions (Ag⁺) are released from the top electrode layer (Ag) and migrate to the bottom electrode layer (FTO) through the resistive switching layer (CsPbI₃). Titanium dioxide (TiO₂) binds to electron-donating defects in the resistive switching layer (CsPbI₃) to remove recombination centers, and the silver ions (Ag⁺) form a metallic filament so that the resistive switching layer is set to a first resistance state. Subsequently, as a second voltage is applied, the metallic filament ruptures so that the resistive switching layer is set to a second resistance state.

Here, the first resistance state may be a low-resistance state (LRS), and the second resistance state may be a high-resistance state (HRS).

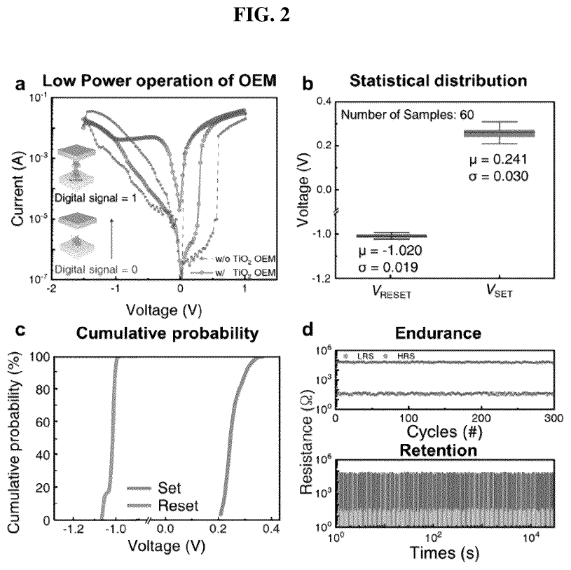

FIG. 2 is a diagram illustrating I-V characteristics, switching voltages (V_{SET}, V_{RESET}), and endurance/retention analysis results of a multifunctional low-power optoelectronic memristor device.

FIG. 2(a) shows a comparison of current-voltage (I-V) characteristics depending on whether a TiO₂-based intermediate layer (120) is present. The I-V characteristics were measured by applying a positive voltage to the top electrode layer and performing a sweep (0 V→1V→0 V→1.5 V→0 V). In the device without the TiO₂ layer, an electroforming process was required to obtain consistent resistive switching (RS) characteristics; during this process, an initial transition from a high-resistance state (HRS) to a low-resistance state (LRS) occurred at a forming voltage of +0.84 V, and in subsequent sweeps, the switching voltage (VSET) was observed at +0.58 V.

In the multifunctional low-power optoelectronic memristor device including a TiO₂ layer as the intermediate layer, performance was significantly improved depending on the thickness of the TiO₂ layer. The initial forming voltages were measured as follows.

$${TiO}_{2} {( 1 nm )}_{-} > 0.8 V ,$$

$${TiO}_{2} {( 3 nm )}_{-} > 0.68 V$$

$${TiO}_{2} {( 5 nm )}_{-} > 0.57 V$$

$${TiO}_{2} {( 10 nm )}_{-} > 0.79 V$$

In subsequent sweeps, V_{SET} and V_{RESET} are as follows.

As a result, in the multifunctional low-power optoelectronic memristor device having a TiO₂ layer with a thickness of 5 nm, switching voltages V_{SET} and V_{RESET} of +0.24 V and −1.02 V were achieved. This indicates that TiO₂ (1 nm and 3 nm)-based devices have insufficient interfacial bonding and cause high leakage current, thereby degrading retention and endurance. In contrast, the TiO₂ (10 nm)-based device shows improved stability, but exhibits an increased V_{SET} due to an increased electron transport distance. Accordingly, selecting an appropriate TiO₂ thickness is important, and in particular, the interface between the perovskite and the bottom electrode significantly affects resistive switching (RS) characteristics. The resistive switching layer (RS layer) forms a conductive network along grain boundaries, and variations in V_{SET} and V_{RESET} occur due to probabilistic rupture and regeneration of metallic filaments.

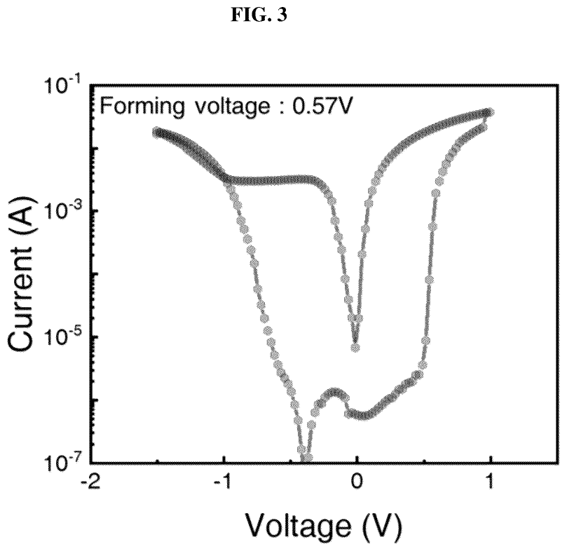

Accordingly, by forming the TiO₂ layer with a thickness of 5 nm, power consumption can be reduced to less than half compared to the conventional technology, and performance can be significantly improved, such as operation under an electric field of 1.3×10₄ V cm₋₁ (see FIG. 3).

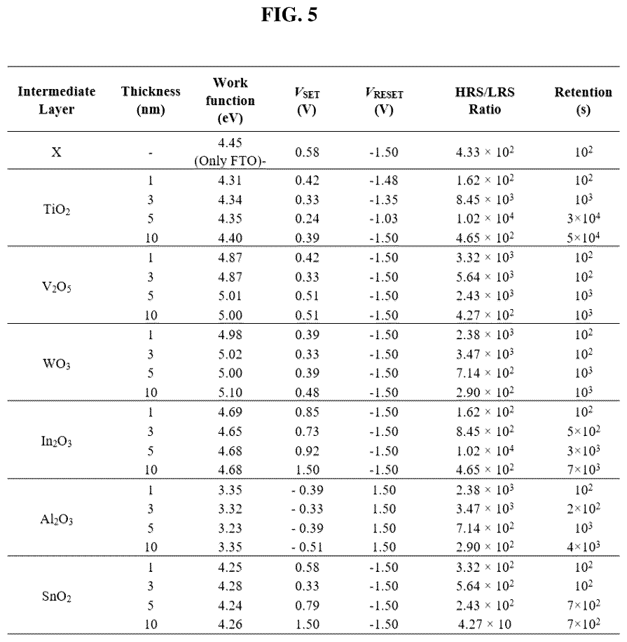

FIG. 4 is a diagram illustrating the I-V characteristics according to the thickness of the intermediate layer when composed of different materials, and these results are summarized in detail in FIG. 5.

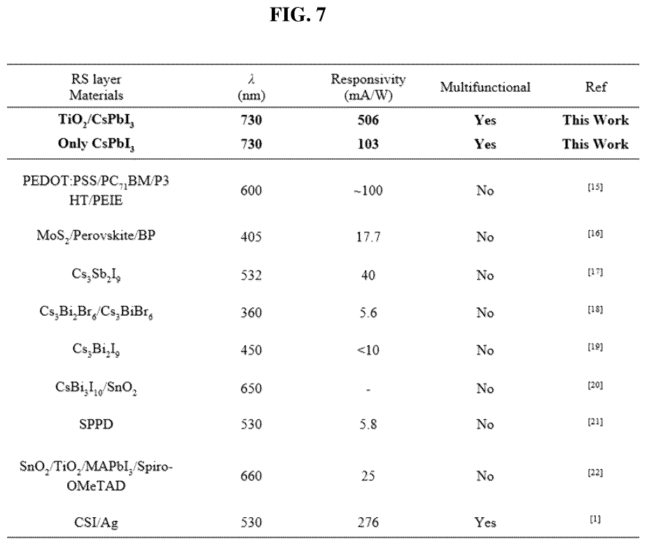

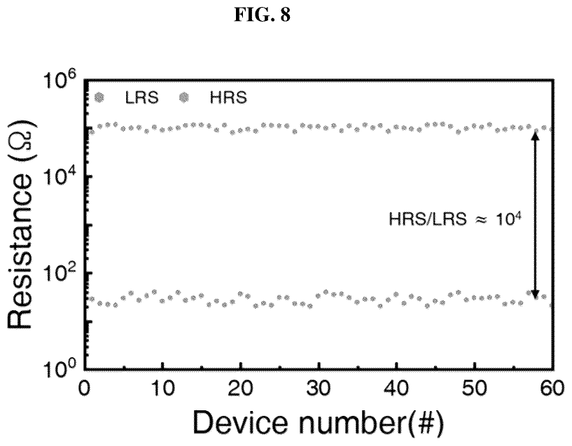

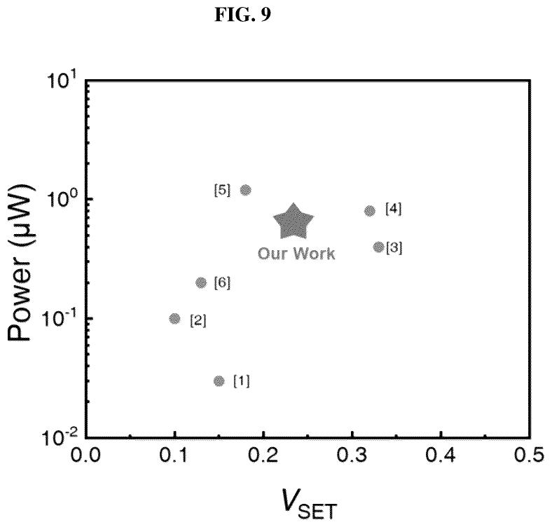

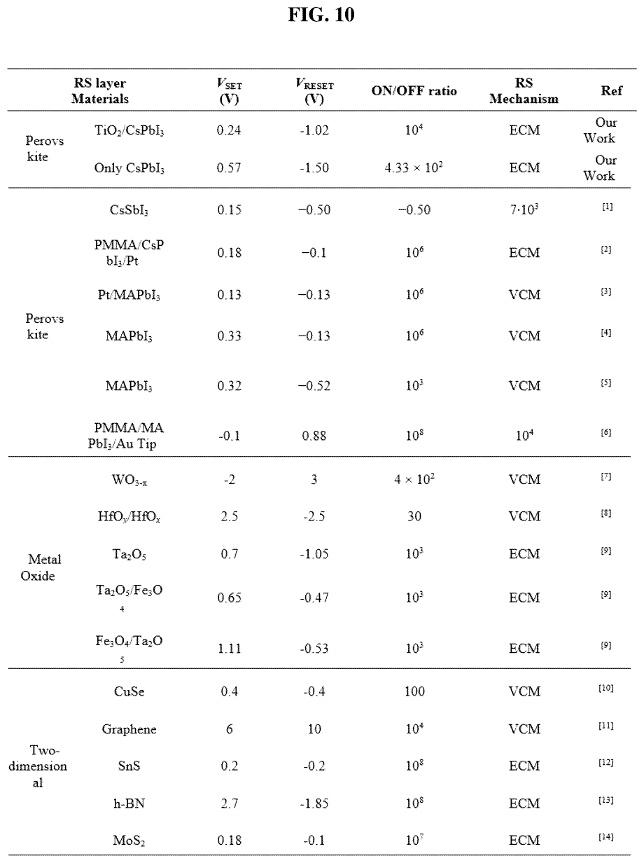

The resistance values under applied voltage pulses were measured from 60 cells of the multifunctional low-power optoelectronic memristor device with TiO₂ inserted, and an average ON/OFF ratio of 10⁴ was obtained, confirming that cell-to-cell variation is minimal. Compared to an ON/OFF ratio of 4.33×10² and a retention time of 10² seconds observed in a conventional multifunctional low-power optoelectronic memristor device, this provides approximately 100 times clearer distinction and indicates suitability for logic circuits representing 0 (OFF state) and 1 (ON state) of a digital signal. The low V_{SET} and minimal operating power achieved in the present disclosure are considered to exhibit state-of-the-art performance among halide-perovskite-, oxide-, and 2D-material-based devices, as shown in FIGS. 5 to 9.

By forming the intermediate layer (120) of TiO₂, energy-band alignment is improved, thereby improving electron transport efficiency and reducing the switching voltage (V_{SET}) from 0.58 V to 0.24 V, indicating that low-power switching can be achieved.

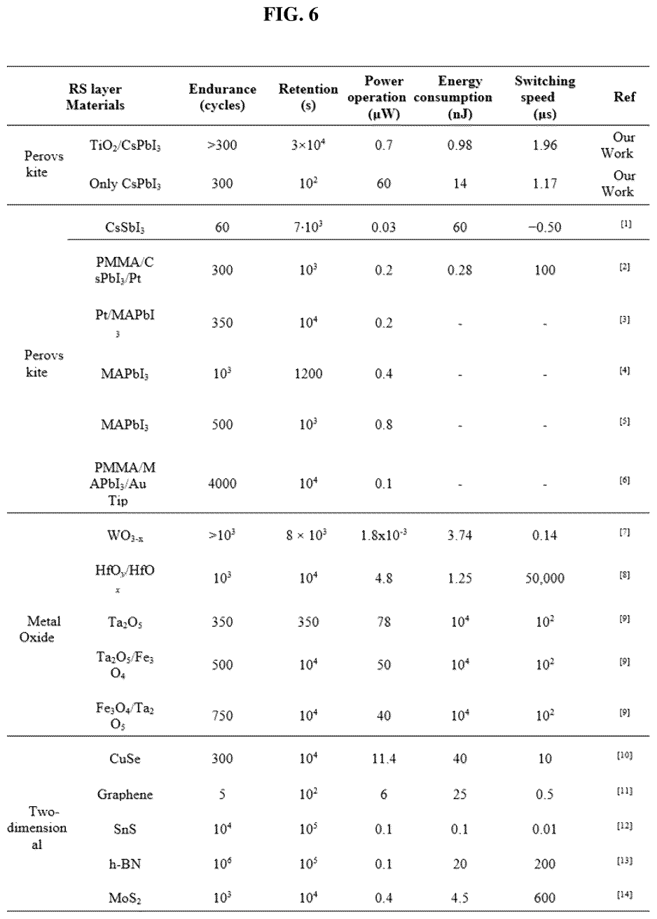

FIGS. 2(b) and 2(c) are diagrams illustrating V_{SET}/V_{RESET} distributions of the multifunctional low-power optoelectronic memristor device having a TiO₂ layer as the intermediate layer. By including the TiO₂ layer as the intermediate layer, the multifunctional low-power optoelectronic memristor device according to one embodiment of the present disclosure exhibits a narrower distribution of V_{SET}/V_{RESET} values, indicating more uniform switching characteristics and higher reliability. Compared to a reference memristor device, which has a power consumption of 70 μW, the TiO₂-inserted multifunctional low-power optoelectronic memristor device operated at 0.7 μW, which is 100 times lower (see FIG. 6). FIG. 2(d) shows endurance and retention characteristics of the multifunctional low-power optoelectronic memristor device having the TiO₂ layer as the intermediate layer. When the TiO₂ layer is used as the intermediate layer as in the present embodiment, it can be seen that the performance is stably maintained even over 300 or more switching cycles. Furthermore, the data retention increases to 10₄ seconds or more, confirming its non-volatile memory characteristics.

As described above, it can be seen that the titanium dioxide (TiO₂) layer improves the conduction band alignment, thereby increasing electron transport efficiency and significantly reducing the power required for switching. These low-power characteristics are highly suitable for IoT and energy-efficient systems.

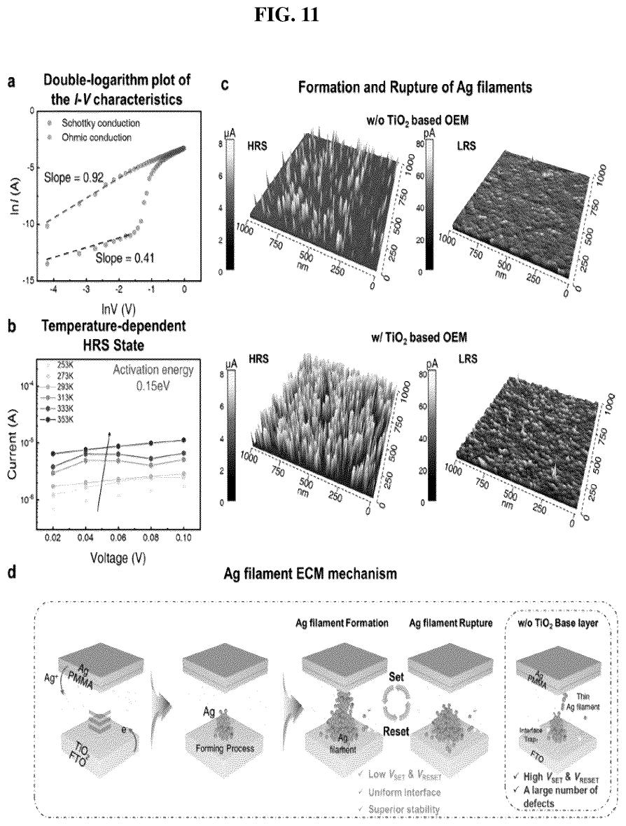

FIG. 11 is a diagram illustrating the switching principle based on the electrochemical metallization (ECM) mechanism according to an embodiment of the present disclosure.

FIG. 11(a) illustrates a log (I)-log (V) curve. The electrochemical metallization (ECM) mechanism can be explained through the logarithmic relationship between current and voltage. Initially, the device is in a high resistance state (HRS) as a conductive filament has not yet been formed; however, at or above a certain threshold voltage, a metallic filament can be formed by the migration of silver ions (Ag⁺), resulting in a low resistance state (LRS).

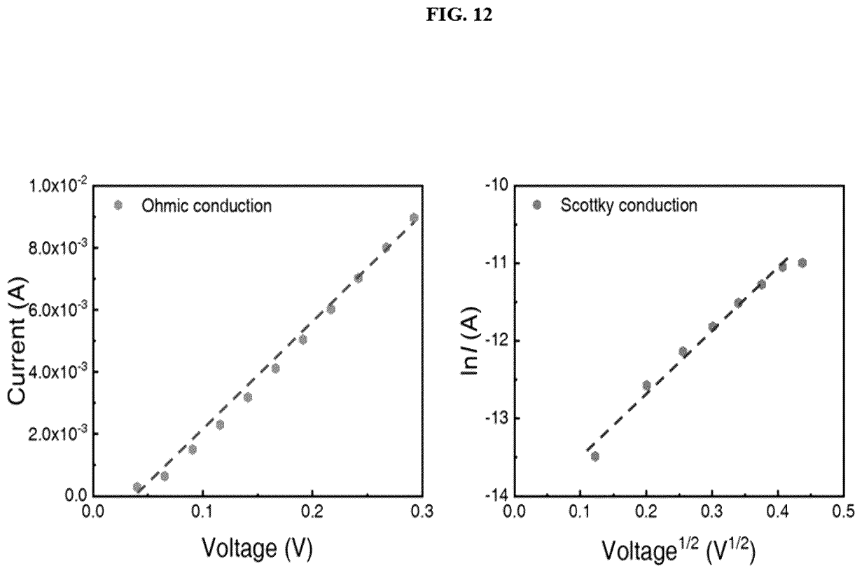

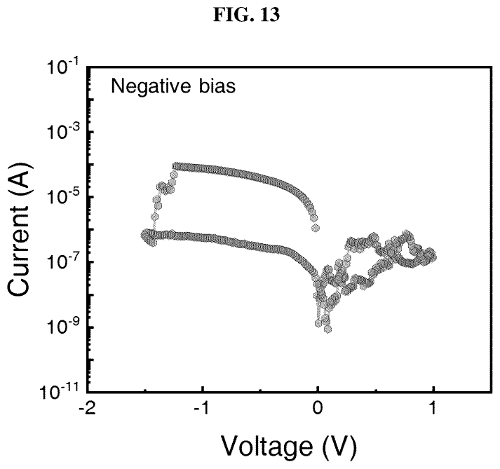

After the abrupt increase in current, the I-V curve in the LRS was plotted for a voltage sweep (+1 V→0 V), confirming that Ohmic conduction is dominant. Meanwhile, the nonlinear I-V curve in the HRS, which exhibited a slope of 0.41 during the voltage sweep (0 V→+0.24 V), was re-plotted as a linear curve (see FIG. 12). The abrupt change in resistance state suggests the presence of an ECM mechanism, in which the Ag electrode is oxidized and metal cations can form a conductive filament. To verify electrochemical reactions associated with the Ag electrode, the initial cell I-V characteristics were measured under negative bias. As shown in FIG. 13, no resistive switching (RS) operation was observed under this condition.

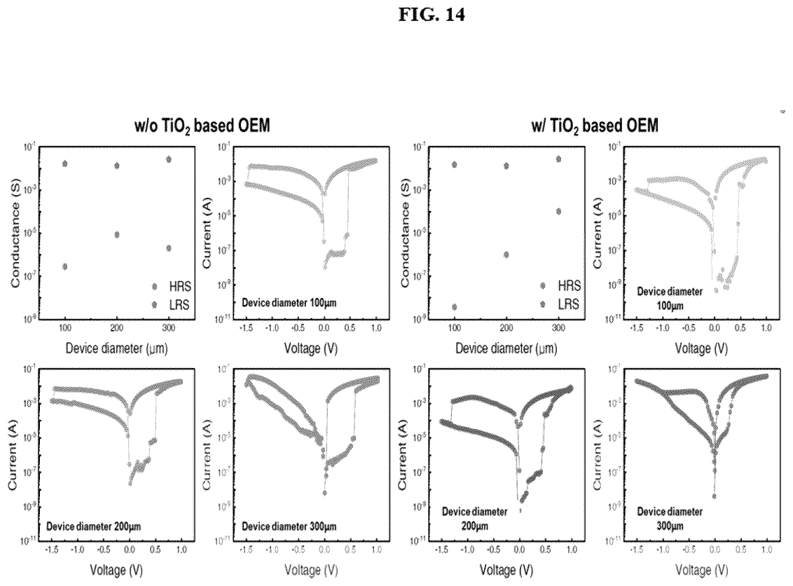

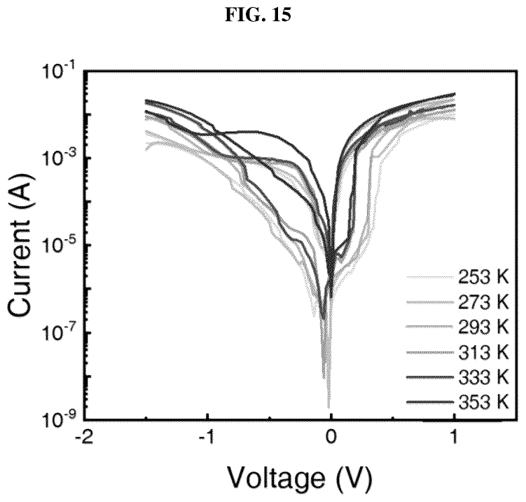

FIGS. 14 and 15 are diagrams illustrating the I-V characteristics of the top electrode measured within a temperature range of 253-353 K.

While the resistance in the HRS is proportional to device size, the resistance in the LRS is independent of device size, indicating that conductivity increases with electrode area. This suggests that a larger electrode area promotes formation of multiple filaments. The I-V characteristics over 253-353 K are shown in FIGS. 14 and 15. For further analysis, the HRS current was replotted as a function of temperature within a voltage range of 0.02-0.10 V, as shown in FIG. 11(b).

FIG. 11(b) is a temperature-dependent I-V curve, showing that the HRS current increases over 253-353 K. This is attributed to migration of Ag⁺ ions and their interaction with trap states. The RS current tends to continuously increase as temperature increases, which is interpreted as being due to migration of Ag metal cations interacting with defects in the switching medium. These results indicate that, as temperature increases, thermal excitation of charge carriers in the perovskite thin film increases, thereby facilitating Ag⁺ migration through the resistive switching layer and reducing V_{SET}.

In contrast, V_{RESET} is related to rupture of the filament caused by Joule heating. At higher temperatures, the filament becomes thinner and its thermal stability decreases, and as a result, V_{RESET} tends to decrease further.

By applying the Arrhenius equation in a voltage range of 0.02-0.10 V, the activation energy (Ea) for charge transport was estimated to be 0.15 eV. This low Ea reflects combined effects of Ag⁺ cation migration and trap states, indicating an environment in which ion migration occurs readily. Accordingly, it was confirmed that the dominant mechanism driving RS is electrical migration of metal ions.

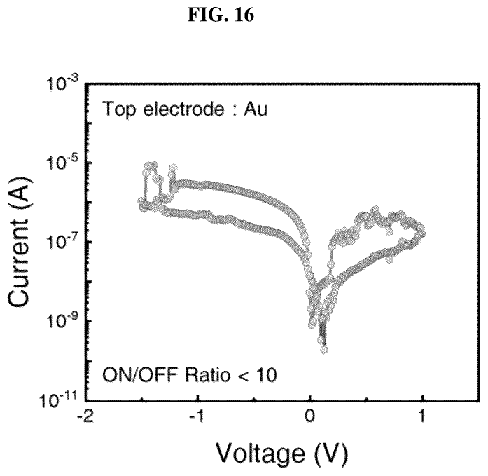

As shown in FIG. 16, a device fabricated using Au as an inert top electrode exhibited almost no ON/OFF ratio (≈10), which strongly supports that Ag⁺ cation migration is the fundamental cause of the ECM-based mechanism.

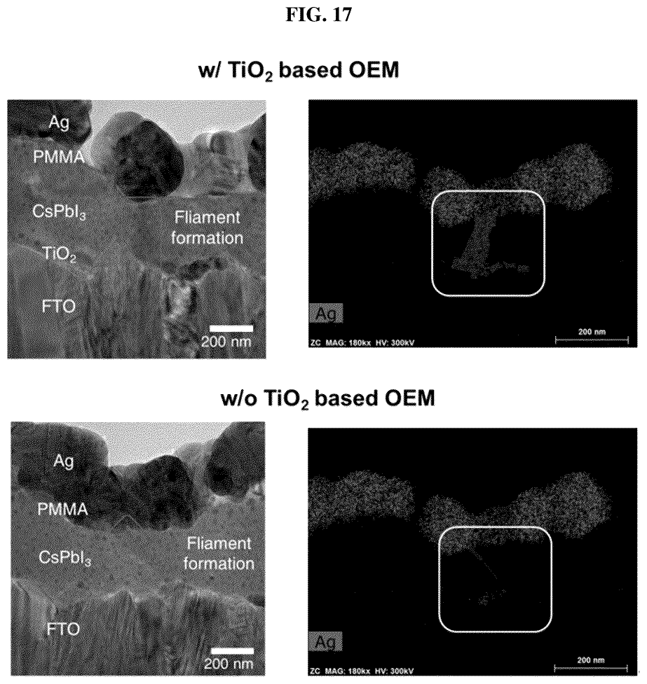

As shown in FIG. 17, TEM energy-dispersive spectroscopy (EDS) analysis was performed to identify main components of the filament responsible for resistive switching, and the presence of silver (Ag) was confirmed. This indicates that Ag is a key constituent of the conductive filament. Cross-sectional TEM images clearly show a filament growth path and revealed that the reference memristor device has a thinner filament than the multifunctional low-power optoelectronic memristor device according to the embodiment of the present disclosure with TiO₂ inserted (FIG. 17).

FIG. 11(c) shows conductive atomic force microscopy (C-AFM) mapping results analyzing the conductive filament. The C-AFM mapping confirmed that filament behavior differs significantly between the ON state and the OFF state. In the ON state, localized high-conductivity regions were observed, indicating filament formation. With reference to FIG. 11(d), the ECM mechanism will be described.

When an electric field is applied, the top electrode layer (150) is oxidized and dissolves, thereby releasing Ag⁺ ions. These cations (Ag⁺) migrate to the bottom electrode layer (FTO) through the resistive switching layer (CsPbI₃), and when Ag⁺ reaches a supersaturated state, Ag⁺ accumulates and a metallic filament spontaneously nucleates and grows to form a metallic filament connecting the bottom electrode layer (FTO) and the top electrode layer.

When the electric field is reversed, the metallic filament dissolves and ruptures, thereby returning to the HRS and being reset.

As shown in FIG. 11(d), when the intermediate layer (120) including a TiO₂ layer is absent, a large number of pinholes are generated.

That is, the multifunctional low-power optoelectronic memristor device including a TiO₂ layer and a halide perovskite (CsPbI₃) exhibited endurance of 300 or more cycles, and storage characteristics were improved by about 100 times compared to a memristor device without the TiO₂ layer. This is interpreted as being because TiO₂ effectively passivates interfacial defects through strong chemical interactions with Pb2⁺ and I⁻ ions. In particular, Ti⁴⁺ ions acting as a Lewis acid bind to iodine vacancies (electron-donating defect sites) on the perovskite surface, thereby suppressing formation of recombination centers, minimizing defects along a charge-transport path, and improving chemical stability of the interface.

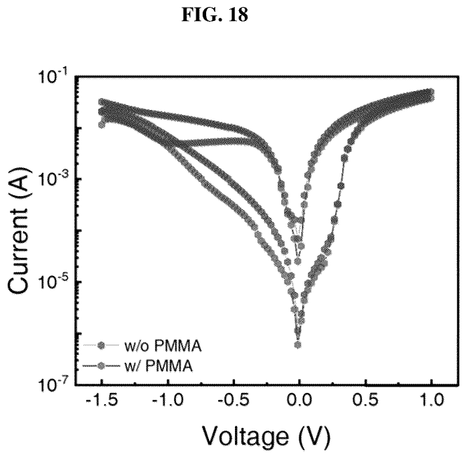

As shown in FIG. 18, the presence of the upper protective layer (PMMA) did not significantly affect RS characteristics of the memristor device because the RS behavior is mainly affected by migration of metal cations within the active layer. In addition, RS operation was not observed with the upper protective layer (PMMA) alone. However, encapsulating the memristor device with the upper protective layer (PMMA) blocks environmental influences, thereby improving overall stability and lifetime of the memristor device.

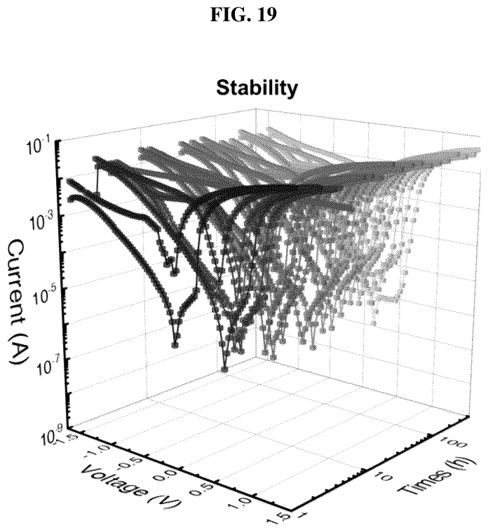

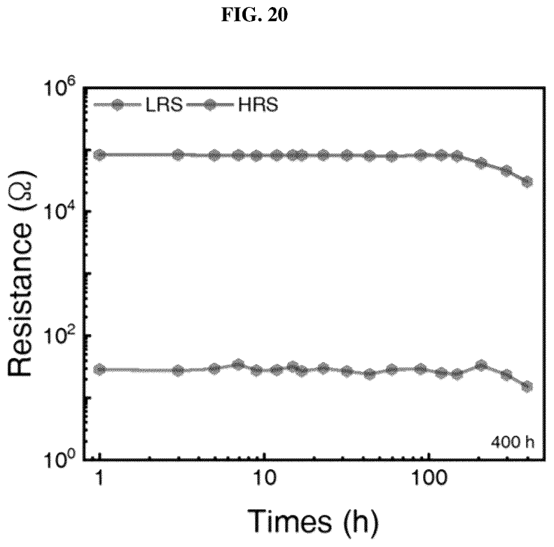

FIGS. 19 and 20 show I-V characteristics and HRS/LRS states of the memristor device with the TiO₂ layer inserted after being stored for 400 hours at room temperature (30% relative humidity). As shown in FIGS. 19 and 20, the memristor device with the TiO₂ layer inserted maintained stability, showing a significant improvement compared to the conventional technology.

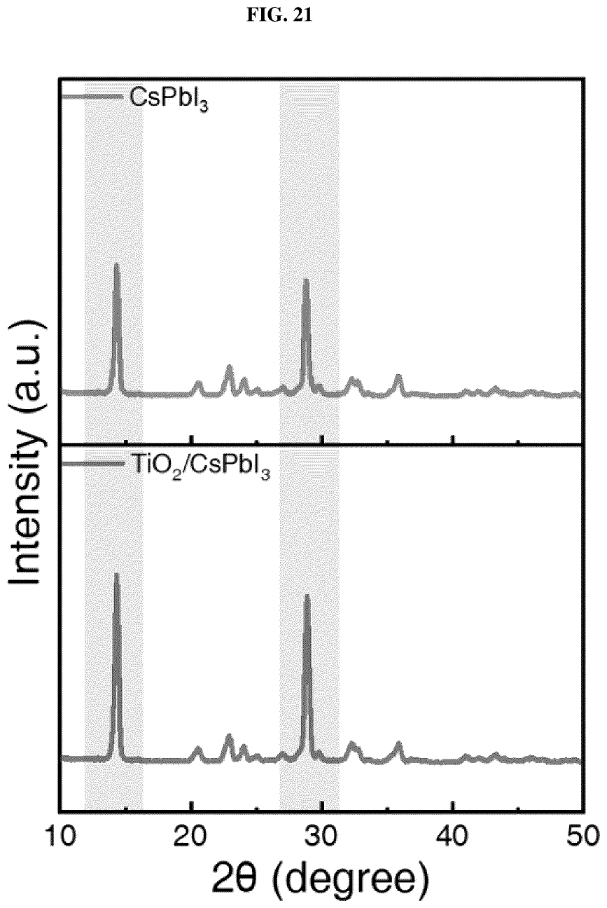

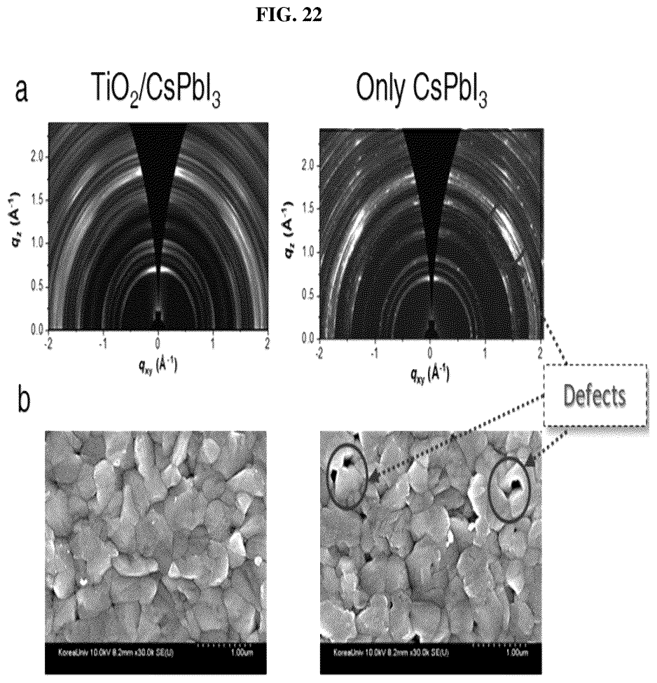

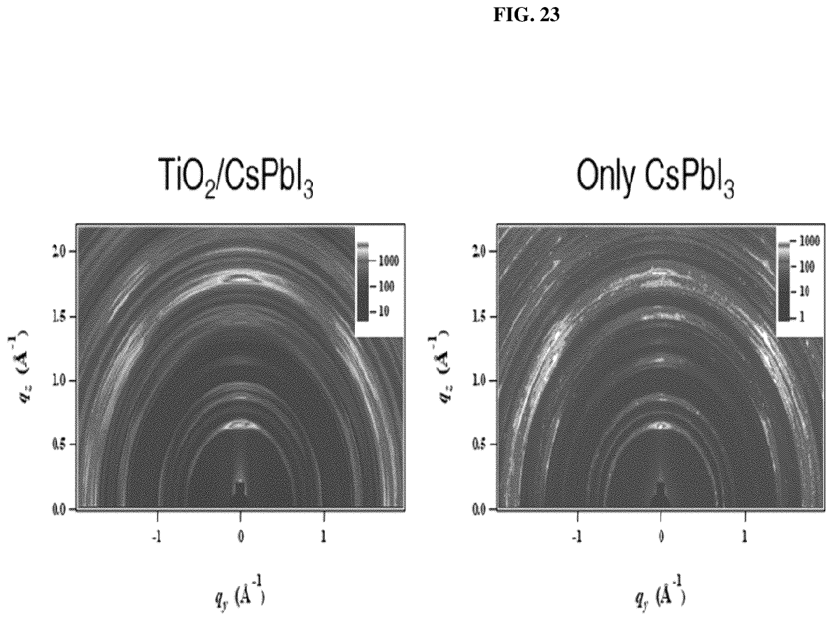

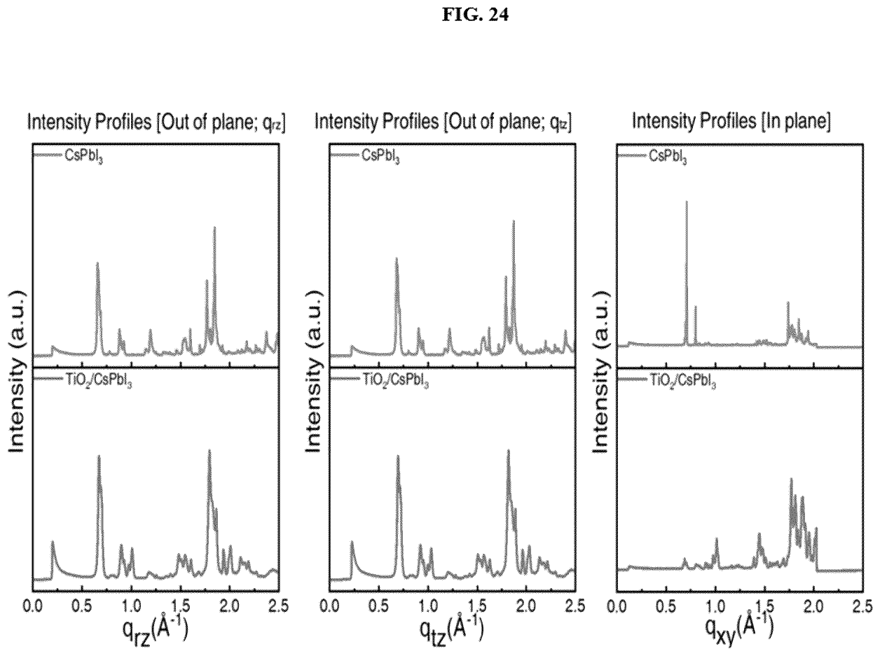

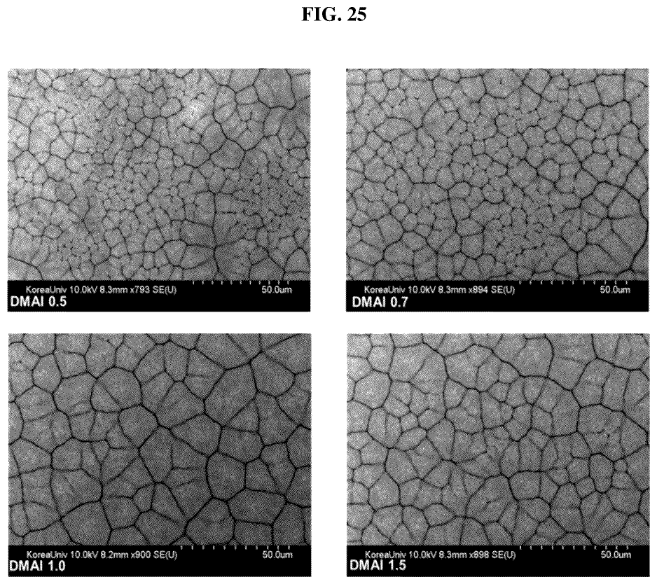

As shown in FIG. 21, crystallinity of the thin film was investigated by X-ray diffraction (XRD) analysis. Distinct diffraction peaks were observed at 14.4° (110) and 29.0° (220), indicating the presence of a perovskite β phase. In particular, these peak intensities were stronger in the sample with the TiO₂ layer inserted than in the untreated perovskite film, suggesting that the TiO₂ layer improved crystallinity of the halide perovskite (CsPbI₃) thin film. In addition, in grazing-incidence wide-angle X-ray scattering (GIWAXS) measurements, ring patterns for the (110) and (220) planes of β-CsPbI₃ showed almost no change, but the film with the TiO₂ layer exhibited fewer defects and a more aligned crystal structure, as shown in FIG. 22(a) through FIG. 24.

FIG. 22 compares crystallinity and surface quality of the halide perovskite (CsPbI₃) layer depending on whether an intermediate layer including TiO₂ is present. FIG. 22(a) shows GIWAXS 2D reciprocal space maps of a TiO₂/halide perovskite (CsPbI₃) film and a single halide perovskite (CsPbI₃) film. In the halide perovskite (CsPbI₃) layer including the TiO₂ layer, it can be seen that crystal size increased and defects decreased, and crystallographic ordering of the β-halide perovskite (CsPbI₃) phase was enhanced, thereby improving electrical characteristics. This supports the conclusion that the TiO₂ layer promotes transition to the β-halide perovskite (CsPbI₃) phase and induces larger crystal growth.

GIWAXS analysis confirmed clear differences in crystal structure and phases between the TiO₂/halide perovskite (CsPbI₃) sample and the single halide perovskite (CsPbI₃) sample. Both samples exhibited distinct diffraction-ring patterns indicative of polycrystalline characteristics in the 2D reciprocal space map. In particular, the TiO₂/halide perovskite (CsPbI₃) sample showed stronger diffraction intensity and more pronounced diffraction rings, suggesting superior crystallinity and larger grain size than the single halide perovskite (CsPbI₃) sample. Although the single halide perovskite (CsPbI₃) sample also showed good crystallinity, the relatively lower diffraction intensity indicates some variation in crystal size or structural orientation.

In terms of crystal orientation, the TiO₂/halide perovskite (CsPbI₃) sample exhibited more uniform alignment, which is considered to be influenced by substrate effects and indicates that TiO₂ plays an important role in controlling orientation during halide perovskite (CsPbI₃) crystal growth. In contrast, the single halide perovskite (CsPbI₃) sample is likely to have generated more defects during growth, and accordingly, its crystal orientation appeared more random. These results suggest that the presence of TiO₂ affects not only the crystal size of halide perovskite (CsPbI₃) but also crystal orientation, thereby inducing more controlled crystal growth.

FIG. 22(b) is a diagram comparing SEM images. The single halide perovskite (CsPbI₃) layer without the TiO₂ layer has many defects and voids, resulting in a non-uniform surface.

In contrast, after insertion of the TiO₂ layer, it can be seen that the grain size of the halide perovskite (CsPbI₃) layer increased and a dense surface was formed.

From the top-view SEM images, the single halide perovskite (CsPbI₃) film exhibited many surface defects, interfacial voids, and small grain size, whereas the TiO₂/halide perovskite (CsPbI₃) film was confirmed to have larger grain size and a dense, defect-free structure (see FIG. 20). These results support the conclusion that the TiO₂ layer promotes transition to the β-CsPbI₃ phase and induces growth of larger crystals.

As shown in FIG. 22, the TiO₂ layer promotes crystallization of the halide perovskite (CsPbI₃) layer to form a denser and more uniform structure, thereby enhancing endurance and reliability of the multifunctional low-power optoelectronic memristor device.

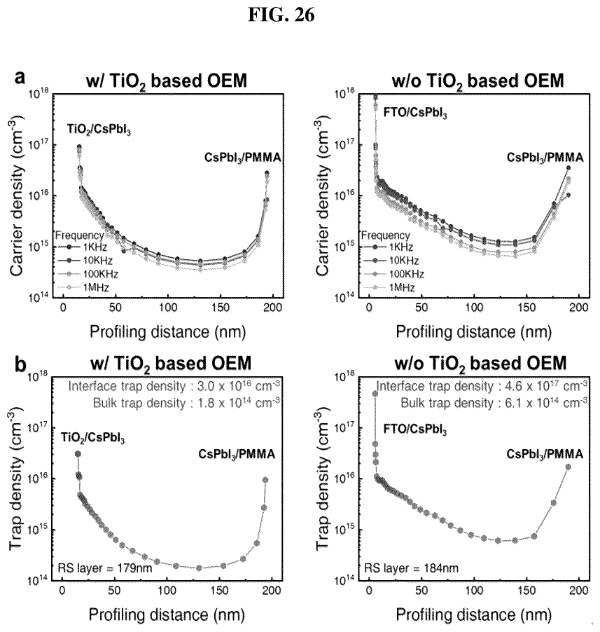

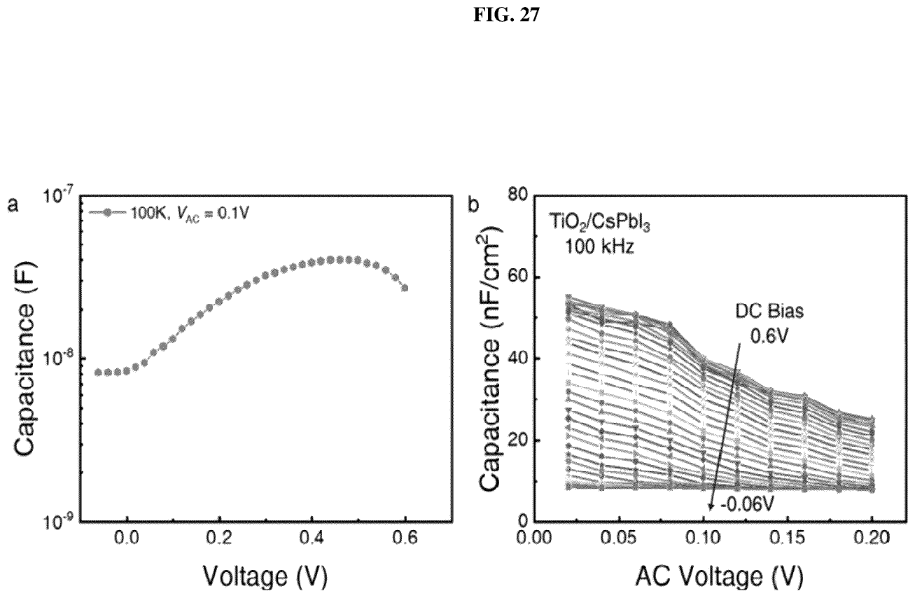

FIG. 26 is a diagram illustrating results comparing trap density and carrier density before and after insertion of the TiO₂ layer. FIG. 26(a) and FIG. 27 show carrier density distributions depending on whether TiO₂ is inserted at various AC frequencies (e.g., 1 kHz to 1 MHz). As shown in FIG. 26(a), when TiO₂ is inserted, an overall more uniform and higher carrier density is observed compared to a device without TiO₂.

This indicates that the TiO₂ layer interacts with electron-donating defects (e.g., iodine deficiency) in the halide perovskite (CsPbI₃) resistive switching layer to form a potential barrier at the interface, thereby suppressing charge recombination and stabilizing charge transport.

Carrier density and trap-state characterization were performed using DLCP and standard capacitance-voltage (C-V) measurement techniques. Carrier density profiles were obtained using the DLCP technique, using a precision LCR meter (Wayne Kerr Electronics 41100) and a probe station (MS Tech MST 4000 A). A source meter (Keithley 2401A) was used for DC dark-chamber characterization, during which voltage sweeps were applied. All measurements were conducted under ambient conditions to ensure consistent and reproducible results. The AC frequency range for DLCP measurements was from 1 kHz to 1 MHz, and carrier density was calculated at each frequency. In the standard C-V measurement, the DC bias was scanned from −0.06 V to 0.6 V to investigate spatial variation of carrier density across the memristor device, and the AC bias amplitude was 20 mV. Likewise, DLCP measurements were performed over the same DC bias range, while the AC bias amplitude was adjusted from 20 m V to 200 m V. An additional offset DC voltage was applied to ensure a consistent maximum forward bias at each AC bias level.

The DLCP technique can evaluate carrier density by analyzing capacitance changes induced by variation of an AC bias (SV) at a given frequency. A nonlinear relationship was observed between the applied AC voltage and the resulting charge change, which can be expressed as a Taylor-series expansion (Equation (1)).

$$\frac{δ D}{δ V} = {C}_{0} + {C}_{1} δ V + {{C}_{2} ( δ V )}^{2} + … \qquad [ Equation 1 ]$$

Here, C₀ represents a base capacitance, and C₁ represents a first-order capacitance component that is important for determining carrier density. The C-V data measured at each DC bias were fitted to a polynomial function using a least-squares method to extract these coefficients. C₁ was found to be particularly sensitive to subtle changes in trap states, and under the measurement conditions, higher-order terms had negligible effects.

The total carrier density including both free carriers and ionized trap states was calculated at various spatial positions using a free-carrier-density (N_{DL}) equation.

NDL is calculated using Equation 2.

$${N}_{DL} = - \frac{{C}_{0}^{3}}{2 q ε {A}^{2} {C}_{1}} \qquad [ Equation 2 ]$$

Here, q denotes the elementary charge, ε denotes the dielectric constant of the semiconductor, A denotes an active area of the junction, C₀ denotes an intercept, and C₁ denotes a slope derived from a linear fit of the C-dV data. The profiling-distance difference reflects trap density variations in real space, which closely matches trap-state changes detected through capacitance measurements. Consistent results were also obtained with values measured by SEM (≈180 nm).

As a result of the analysis, a clear correlation was confirmed between the spatial capacitance variation and the trap distribution, with the trap density appearing significantly higher in the region near the interface. The trap density was calculated by subtracting the carrier density estimated under high-frequency AC conditions from the total carrier density measured under low-frequency AC conditions. The spatial profiling distance can be calculated using Equation 3.

$$d = ε A / {C}_{0} \qquad [ Equation 3 ]$$

FIG. 26(b) is a diagram comparing the reduction in trap density at the thin-film interface depending on the presence or absence of the titanium dioxide (TiO₂) layer. It can be observed that the trap density decreased approximately 15-fold, from 4.6×10¹⁷ cm⁻³ before the insertion of the TiO₂ layer to 3.0×10¹⁶ cm⁻³ after its insertion. This indicates that the conductive filament formation is stabilized, resulting in more uniform switching characteristics.

In addition, the bulk trap density of the thin film also decreased by about 3 times, from 6.1×10¹⁴ cm₋₃ to 1.8×10¹⁴ cm⁻³.

That is, it can be seen that the TiO₂ layer interacts with electron-donating defects (e.g., iodine deficiency) in the halide perovskite (CsPbI₃) layer serving as a resistive switching layer, thereby forming a potential barrier at the interface; through suppression of charge recombination, crystallinity is improved, and stability and reliability of the memristor device are enhanced. The TiO₂ layer reduces the potential barrier and bulk defects at the interface, thereby stabilizing switching characteristics of the resistive switching layer (130), reducing power consumption, and significantly improving performance of the memristor device.

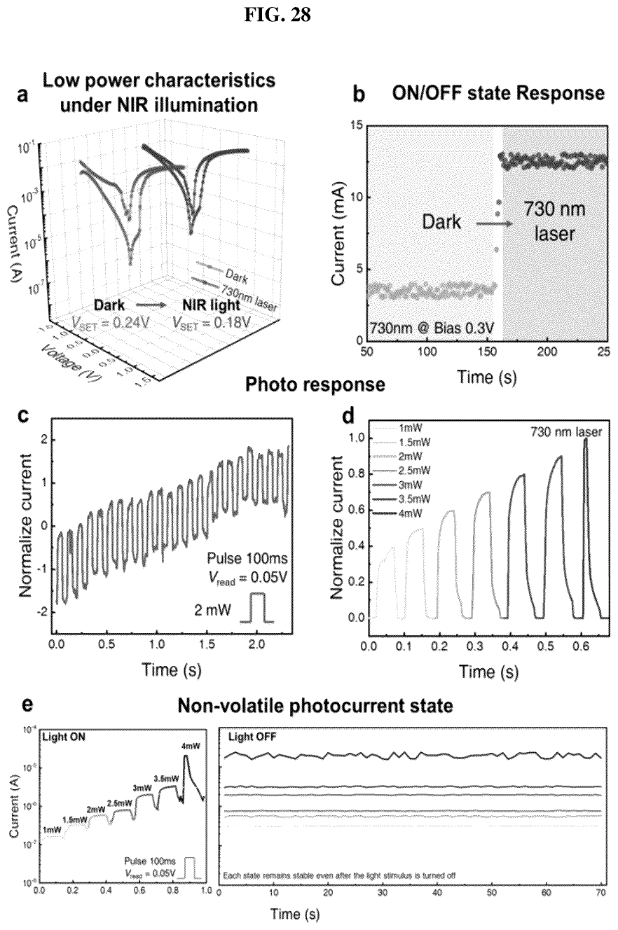

FIG. 28 is a diagram comparing electrical responses to optical inputs in a multifunctional low-power optoelectronic memristor device according to an embodiment of the present disclosure.

FIG. 28(a) shows an I-V curve under 730 nm laser illumination. Under 730 nm laser illumination, VSET decreased from 0.24 V to 0.18 V, indicating that the 730 nm laser illumination can facilitate a set operation. That is, photo-generated charges may be generated in the resistive switching layer (CsPbI₃) in response to 730 nm near-infrared laser illumination.

Additionally, FIG. 28(b) shows ON/OFF-state current changes, in which the device transitions to the LRS (ON) under 730 nm laser illumination and returns to the HRS (OFF) when the illumination is removed.

FIG. 28(c) shows responsiveness to optical pulses, and it can be seen that a stable state is maintained even after application of 20 optical pulses (2 mW, 100 ms). That is, it is shown that the 730 nm laser optical input can induce persistent state changes.

FIG. 28(d) shows current changes according to optical intensity, and it can be seen that, in the HRS, the current increases as optical intensity increases, indicating that the 730 nm laser illumination has an effect of reinforcing a conductive path.

FIG. 28(e) shows non-volatile data retention, and it can be seen that data is stably maintained even after 50 optical pulses. This confirms non-volatile memory characteristics based on the 730 nm laser optical input.

That is, the electrical state is controlled in response to the 730 nm laser optical input, thereby enhancing data retention and providing reliability as a memristor device.

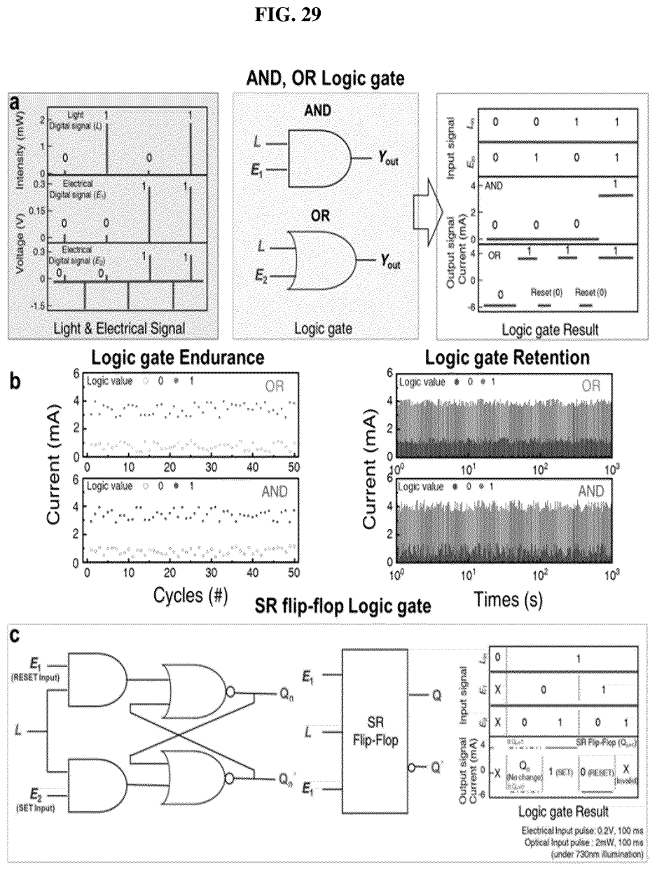

FIG. 29 is a diagram illustrating logic operations and flip-flop implementation using both optical and electrical inputs based on a multifunctional low-power optoelectronic memristor device according to an embodiment of the present disclosure.

FIG. 29(a) shows AND/OR gate operations. For an AND gate, when both an electrical signal (0.2 V) and an optical signal (2 mW or more) are input, the device switches to the LRS and outputs logic “1”. For an OR gate, when either an electrical signal (0.3 V) or an optical signal is input, the device switches to the LRS and can output logic “1”.

FIG. 29(b) shows repeatability of logic operations, indicating that accurate logic operations can be performed over multiple cycles.

FIG. 29(c) shows a flip-flop circuit, in which state storage and transition can be performed using two AND gates, OR gates, and one NOT gate, and a state (Q/Q′) can be maintained or switched depending on an input signal.

This indicates that multifunctional logic operations can be implemented with a simpler structure than conventional transistor-based circuits, thereby contributing to miniaturization and energy efficiency.

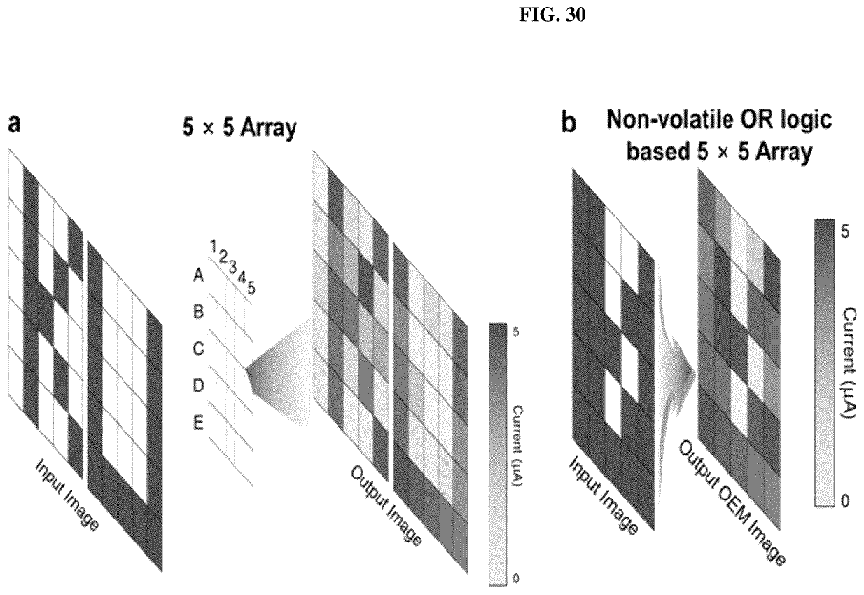

FIG. 30 is a diagram illustrating experiments demonstrating image recognition and non-volatile data storage using an array of multifunctional low-power optoelectronic memristor devices according to an embodiment of the present disclosure.

FIG. 30(a) shows image recognition using a 5×5 optoelectronic memristor array. A “KU”-shaped pattern receives 730 nm optical pulses, and illuminated cells are identified through current mapping. When an optical signal in the “KU” shape is input to the array, cells switched to the LRS can store the pattern.

FIG. 30(b) is a non-volatile output-current image, showing that portions of two shapes were illuminated at least once, thereby demonstrating that the array can recognize and maintain image patterns.

That is, the memristor device can simultaneously perform image recognition and data storage, indicating suitability for IoT and neural-network-based applications.

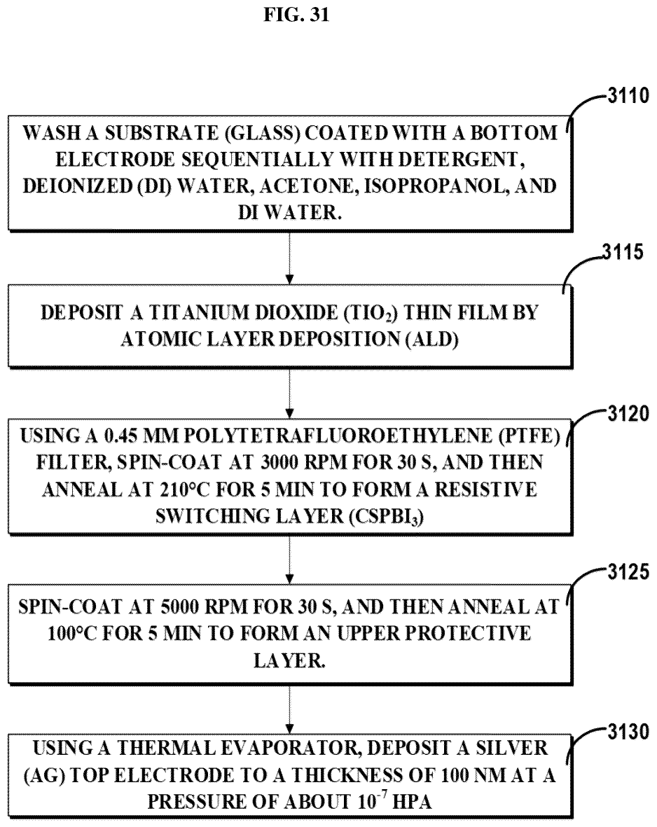

FIG. 31 is a flowchart illustrating a method of manufacturing a multifunctional low-power optoelectronic memristor device according to an embodiment of the present disclosure.

In operation 3110, a substrate (glass) coated with a bottom electrode is washed sequentially with detergent, deionized (DI) water, acetone, isopropanol, and DI water.

In operation 3115, a titanium dioxide (TiO₂) thin film is deposited by atomic layer deposition (ALD). During the deposition, the chamber temperature may be set to 200° C. and the pressure may be set to 7 m Torr. In addition, TTIP may be used as a precursor and H₂O may be used as a reactant, a canister temperature may be maintained at room temperature, and a line temperature may be set to 80° C.

Sequential ALD growth of TiO₂ may include injecting a TTIP pulse for 2 seconds followed by purging with Ar gas for 10 seconds, and injecting an H₂O pulse for 2 seconds followed by purging with Ar gas for 15 seconds. By repeating this cycle 98 times, a TiO₂ layer having a thickness of 5 nm may be formed as the intermediate layer.

In operation 3120, after spin-coating at 3000 rpm for 30 seconds using a 0.45 μm polytetrafluoroethylene (PTFE) filter, annealing is performed at 210° C. for 5 minutes to form a resistive switching layer (CsPbI₃). A 0.6 M CsPbI₃ perovskite precursor was prepared by dissolving CsI, PbI₂, and DMAI in DMF at a 1:1 molar ratio, and the mixture was stirred overnight in an environment having 15-20% relative humidity.

In operation 3125, after spin-coating at 5000 rpm for 30 seconds, annealing is performed at 100° C. for 5 minutes to form an upper protective layer (PMMA dissolved in chlorobenzene at 5 mg/mL).

Finally, in operation 930, a silver (Ag) top electrode having a thickness of 100 nm may be deposited using a thermal evaporator at a pressure of about 10⁻⁷ hPa. A shadow mask was used to define an electrode pattern. An active area covered by the top electrode was estimated to be about 0.07 mm².

A 5×5 array was fabricated on a 25 mm×25 mm substrate. The fabrication process started by depositing five bottom electrodes each having a size of 4 mm×20 mm and formed of FTO, and then a TiO₂ layer was deposited by ALD to secure precise thickness and uniformity. Thereafter, a resistive switching layer and an upper protective layer (PMMA) were sequentially deposited on the TiO₂ layer

Thereafter, using a pattern mask, five Ag top electrodes each having a size of 4 mm×20 mm were deposited in a direction orthogonal to the bottom electrodes to form a 5×5 array structure. Deposition of each layer was carefully optimized to secure uniformity and reproducibility across all cells.

The present disclosure was described above focusing on the embodiments thereof. It would be understood by those skilled in the art that the present disclosure may be implemented in a modified form without departing from the scope of the present disclosure. Therefore, the disclosed embodiments should be considered in terms of explaining, not limiting. The scope of the present disclosure is shown in the claims, not in the above description, and all differences within an equivalent range should be construed as being included in the present disclosure.

What is claimed is:

1. A multifunctional low-power optoelectronic memristor device comprising:
a bottom electrode layer;
an intermediate layer formed on the bottom electrode layer and including titanium dioxide (TiO₂);
a resistive switching layer formed on the intermediate layer and configured to switch a resistance state;
an upper protective layer formed on the resistive switching layer; and
a top electrode layer formed on the upper protective layer,
wherein the resistive switching layer is a halide perovskite material layer.

2. The multifunctional low-power optoelectronic memristor device of claim 1,
wherein the intermediate layer is formed to a thickness of 1 nm to 5 nm by atomic layer deposition (ALD), and has a thickness of 5 nm to control a formation position and a size of a conductive filament in the halide perovskite material layer.

3. The multifunctional low-power optoelectronic memristor device of claim 1,
wherein the halide perovskite material layer comprises CsPbI₃.

4. The multifunctional low-power optoelectronic memristor device of claim 1,
wherein, when a voltage is applied to the bottom electrode layer and the top electrode layer, the titanium dioxide (TiO₂) binds to electron-donating defects in the halide perovskite material layer to remove recombination centers, thereby controlling a formation position and a size of a filament.

5. The multifunctional low-power optoelectronic memristor device of claim 1,
wherein: in response to application of a first voltage, silver ions (Ag⁺) are released from a top electrode (Ag) and migrate to a bottom electrode (FTO) through the resistive switching layer (CsPbI₃), titanium dioxide (TiO₂) binds to electron-donating defects in the resistive switching layer (CsPbI₃) to remove recombination centers, and the silver ions (Ag⁺) form a metallic filament such that the resistive switching layer is set to a first resistance state; and
in response to application of a second voltage, the metallic filament is ruptured such that the resistive switching layer is set to a second resistance state.

6. The multifunctional low-power optoelectronic memristor device of claim 5,
wherein a 730 nm near-infrared laser is irradiated, and photo-generated charges are generated in the resistive switching layer (CsPbI₃) according to irradiation of the 730 nm near-infrared laser.

7. The multifunctional low-power optoelectronic memristor device of claim 6,
wherein the first voltage is 0.24 V to 0.18 V, and under irradiation of the 730 nm near-infrared laser, the first voltage is 0.18 V.

8. The multifunctional low-power optoelectronic memristor device of claim 5,
wherein the first voltage and the second voltage have opposite polarities.

9. A method of manufacturing a multifunctional low-power optoelectronic memristor device, the method comprising:
coating a bottom electrode;
depositing a titanium dioxide (TiO₂) thin film having a thickness of 5 nm on the bottom electrode by atomic layer deposition;
forming a resistive switching layer on the titanium dioxide (TiO₂) thin film using a polytetrafluoroethylene (PTFE) filter;
forming an upper protective layer on the resistive switching layer; and
depositing a silver top electrode to a thickness of 100 nm at a pressure of 10⁻⁷ hPa using a thermal evaporator.
